(19) United States
(12) Patent Application Publication
(10) Pub. No.: US 2026/0123289 A1
(43) Pub. Date: Apr. 30, 2026

(54) MAGNETIC MEMORY DEVICE AND ELECTRONIC DEVICE INCLUDING THE SAME

(71) Applicant: Samsung Electronics Co., Ltd., Suwon-si (KR)

(72) Inventors: Soichiro MIZUSAKI, Suwon-si (KR); Jeongchun RYU, Suwon-si (KR); Jungsik PARK, Suwon-si (KR); Atsushi OKADA, Suwon-si (KR); Naoki HASE, Suwon-si (KR)

(73) Assignee: Samsung Electronics Co., Ltd., Suwon-si (KR)

(21) Appl. No.: 19/003,347

(22) Filed: Dec. 27, 2024

(30) Foreign Application Priority Data
Dec. 28, 2023 (KR) 10-2023-0195612

(51) Int. Cl. H10N 50/85; G11C 11/16; H10B 61/00

(52) U.S. Cl. CPC H10N 50/85; G11C 11/161; H10B 61/22

(57) ABSTRACT

A magnetic memory device may include an orbital Hall conductance (OHC) material layer including a non-heavy metal material and configured to generate an orbital Hall current, a conversion layer on the OHC material layer and configured to convert an orbital Hall current generated by the OHC material layer into a spin Hall current, and a magnetization switching layer on the conversion layer and including a magnetic material. The OHC material layer may include an oxide.

### CROSS-REFERENCE TO RELATED APPLICATION

This application claims the benefit of Korean Patent Application No. 10-2023-0195612, filed on Dec. 28, 2023 in the Korean Intellectual Property Office, the disclosure of which is incorporated herein in its entirety by reference.

### BACKGROUND

### 1. Field

The disclosure relates to a magnetic memory device and an electronic device including the magnetic memory device.

### 2. Description of the Related Art

Magnetic memory devices, such as magnetic random-access memory (MRAM), store data using a resistance change of a magnetic tunnel junction device. The resistance of a magnetic tunnel junction device may vary with the magnetization direction of a free layer. For example, when the magnetization direction of a free layer is the same as the magnetization direction of a pinned layer, the magnetic tunnel junction device may have a low resistance value, and when the magnetization directions are opposite to each other, the magnetic tunnel junction device may have a high resistance value. When a memory device utilizes such characteristics, for example, a magnetic tunnel junction device may represent data ‘0’ when having a low resistance value and data ‘1’ when having a high resistance value.

Such a magnetic memory device may be non-volatile, may be capable of performing a high-speed operation, may have high durability, and the like. For example, spin-transfer torque-magnetic RAM (STT-MRAM), which is currently under mass production, may have an operating speed of about 5 nsec to about 100 nsec and excellent data retention of 10 or more years. Furthermore, spin-orbit torque (SOT)-MRAM, which has a spin polarization direction that is perpendicular to the magnetization direction, may have a very fast operating speed of 5 nsec or less, which is faster than that of the STT-MRAM. Furthermore, as a write current path and a read current path of the SOT-MRAM are different from each other, the SOT-MRAM may have more stable durability. For this SOT-MRAM, various materials to generate the SOT have been researched, and furthermore, methods to realize magnetization switching with a low operating current have been sought.

### SUMMARY

Provided is a magnetic memory device and an electronic device including the magnetic memory device.

Additional aspects will be set forth in part in the description which follows and, in part, will be apparent from the description, or may be learned by practice of the presented embodiments.

According to an example embodiment of the disclosure, a magnetic memory device may include an orbital Hall conductance (OHC) material layer including a non-heavy metal material and configured to generate an orbital Hall current; a conversion layer on the OHC material layer and configure to convert an orbital Hall current generated by the OHC material layer into a spin Hall current, and including oxide; and a magnetization switching layer on the conversion layer and including a magnetic material.

In some embodiments, the conversion layer may include an oxide containing Ni.

In some embodiments, the conversion layer may include a Ni oxide of a non-stoichiometric composition.

In some embodiments, the conversion layer may include an oxide of a ferromagnetic material.

In some embodiments, the conversion layer may include an Al oxide, a Tb oxide, a Mg oxide, a Si oxide, a Ti oxide, a V oxide, a Cr oxide, a Fe oxide, a Co oxide, a Zr oxide, a Y oxide, a Nb oxide, a Ru oxide, a Hf oxide, a W oxide, a rare-earth element, or a transition metal oxide.

In some embodiments, the OHC material layer may include Ca, Sc, Ti, V, Cr, Mn, Fe, Co, Ni, Y, Zr, Nb, Mo, or Ru.

In some embodiments, the OHC material layer may include a 3d transition metal or a 4d transition metal.

In some embodiments, the OHC material layer may not include Pt, Ta, or beta-W.

In some embodiments, the magnetization switching layer may include a free layer, a tunnel barrier layer, and a pinned layer, which are sequentially arranged on the conversion layer.

In some embodiments, the magnetic memory device may further include a first electrode and a second electrode electrically connected to opposite sides of the OHC material layer, respectively, and a third electrode electrically connected to the pinned layer.

In some embodiments, the first electrode and second electrode may each include a same material as the OHC material.

In some embodiments, the magnetic memory device may further include a magnetic layer. The magnetic layer may be between the first electrode and the OHC material layer or the magnetic layer may be between the second electrode and the OHC material layer.

In some embodiments, the magnetic memory device may further include a seed layer and an insulating layer. The seed layer may be between the insulating layer and the OHC material layer.

In some embodiments, a thickness of the OHC material layer may be 0.5 nm or more.

In some embodiments, the thickness of the conversion layer may be 0.5 nm to 5 nm.

According to an embodiment of the disclosure, a memory device may include a plurality of memory cells. Each of the plurality of memory cells may include a magnetic memory device and a switching device connected to the magnetic memory device. The magnetic memory device may include an orbital Hall conductance (OHC) material layer including a non-heavy metal material and configured to generate an orbital Hall current; a conversion layer on the OHC material layer and configured to convert an orbital Hall current generated by the OHC material layer into a spin Hall current, and including an oxide; and a magnetization switching layer on the conversion layer and including a magnetic material.

In some embodiments, the conversion layer may include an oxide containing Ni.

In some embodiments, the conversion layer may include a Ni oxide of a non-stoichiometric composition.

In some embodiments, the conversion layer may include an Al oxide, a Tb oxide, a Mg oxide, a Si oxide, a Ti oxide, a V oxide, a Cr oxide, a Fe oxide, a Co oxide, a Zr oxide, a Y oxide, a Nb oxide, a Ru oxide, a Hf oxide, a W oxide, a rare-earth element, or a transition metal oxide.

In some embodiments, the OHC material layer may include Ca, Sc, Ti, V, Cr, Mn, Fe, Co, Ni, Y, Zr, Nb, Mo, or Ru.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view showing a schematic structure of a magnetic memory device according to an embodiment;

FIGS. 2A and 2B are cross-sectional views of the magnetic memory device of FIG. 1, showing examples of a magnetization direction of a magnetization switching layer according to a direction of a write current applied to the magnetic memory device;

FIG. 3 is a computer-simulated graph of a magnetization switching operation of a magnetic memory device according to an embodiment;

FIG. 4 is a computer-simulated graph of a magnetization switching operation of a magnetic memory device according to a comparative example;

FIG. 5 is a graph showing a comparison of a magnetization switching effect between a magnetic memory device according to an embodiment and a magnetic memory device according to a comparative example;

FIG. 6 is a cross-sectional view schematically showing a structure of a magnetic memory device according to another embodiment;

FIG. 7 is a cross-sectional view schematically showing a structure of a magnetic memory device according to another embodiment.

FIG. 8 is a cross-sectional view schematically showing a structure of a magnetic memory device according to another embodiment;

FIG. 9 schematically illustrates one memory cell including a magnetic memory device according to an embodiment;

FIG. 10 is a circuit diagram schematically showing a configuration of a memory device including a plurality of memory cells illustrated in FIG. 9; and

FIG. 11 is a conceptual view schematically showing a device architecture to be applied to an example electronic device.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Hereinafter, an embodiment is described in detail with reference to the accompanying drawings. The described embodiment is just an example, and various modifications are possible from the embodiments. Throughout the drawings, like reference numerals denote like elements, and sizes of components in the drawings may be exaggerated for convenience of explanation and clarity.

In the following description, when a constituent element is disposed “above” or “on” to another constituent element, the constituent element may be only directly on the other constituent element or above the other constituent elements in a non-contact manner.

Terms such as “first” and “second” are used herein merely to describe a variety of constituent elements, but the constituent elements are not limited by the terms. Such terms are used only for the purpose of distinguishing one constituent element from another constituent element.

As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or components, but do not preclude the presence or addition of one or more other features or components.

Furthermore, terms such as “ . . . portion,” “ . . . unit,” “ . . . module,” and “ . . . block” stated in the specification may signify a unit to process at least one function or operation and the unit may be embodied by hardware, software, or a combination of hardware and software.

The steps of all methods described herein can be performed in any suitable order unless otherwise indicated herein or otherwise clearly contradicted by context. Furthermore, the use of any and all examples, or language (e.g., “such as”) provided herein, is intended merely to better illuminate the disclosure and does not pose a limitation on the scope of the disclosure unless otherwise claimed.

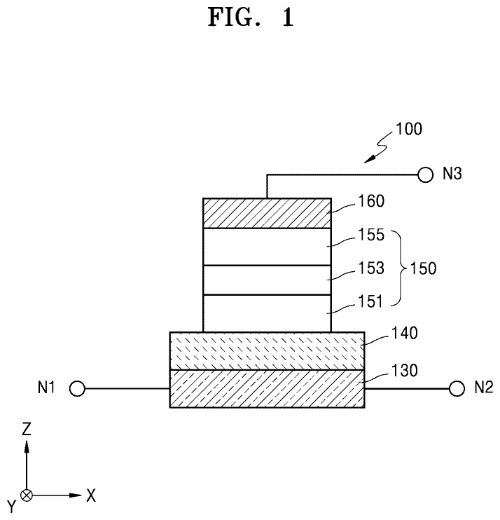

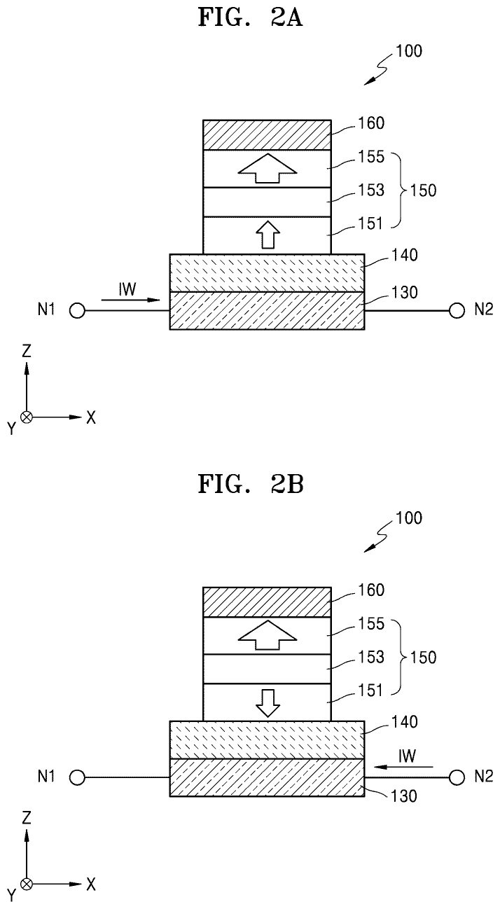

FIG. 1 is a cross-sectional view showing a schematic structure of a magnetic memory device 100 according to an embodiment, and FIGS. 2A and 2B are cross-sectional views of the magnetic memory device 100 of FIG. 1, showing examples of a magnetization direction of a magnetization switching layer 150 according to a direction of a write current applied to the magnetic memory device 100.

The magnetic memory device 100 may include an orbital Hall conductance (OHC) material layer 130, a conversion layer 140, and a magnetization switching layer 150.

The OHC material layer 130 may have a material having OHC. The OHC refers to the property of generating an orbital Hall current according to the orbital Hall effect. A current generated according to the orbital Hall effect may be referred to as an orbital Hall current, or briefly an orbital current.

The OHC material layer 130 may include an element having the OHC or an alloy thereof. The OHC material layer 130 may include an element having a high OHC or an alloy thereof. The OHC represented by the OHC material layer 130 may be, for example, greater than spin Hall conductance (SHC) represented by a heavy metal material. The OHC represented by the OHC material layer 130 may be greater than SHC represented by Pt. The OHC represented by the OHC material layer 130 may be several times or more, for example, two times, three times, or more, than the SHC represented by Pt.

The OHC material layer 130 may include a non-heavy metal material. For example, the OHC material layer 130 may include Ca, Sc, Ti, V, Cr, Mn, Fe, Co, Ni, Y, Zr, Nb, Mo, or Ru. The OHC material layer 130 may include a 3d transition metal or a 4d transition metal.

The OHC material layer 130 does not include a heavy metal material, for example, Pt, Ta, beta-W, and the like.

The thickness of the OHC material layer 130 may be about 0.5 nm or more. The thickness of the OHC material layer 130 may be about 100 nm or less. The thickness of the OHC material layer 130 may be about 10 nm to about 100 nm.

The conversion layer 140, which is disposed on the OHC material layer 130, may convert the orbital Hall current generated by the OHC material layer 130 into a spin Hall current. The spin Hall current may be briefly referred to as a spin current.

The conversion layer 140 may include an oxide containing Ni. The conversion layer 140 may include Ni oxide of a non-stoichiometric composition, for example, a composition represented by NiO+Ni.

The conversion layer 140 may include an oxide of a ferromagnetic material. The conversion layer 140 may include Al oxide, Tb oxide, Mg oxide, Si oxide, Ti oxide, V oxide, Cr oxide, Fe oxide, Co oxide, Zr oxide, Y oxide, Nb oxide, Ru oxide, Hf oxide, W oxide, an oxide of a rare-earth element, or transition metal oxide.

The thickness of the conversion layer 140 may be 0.5 nm or more. The thickness of the conversion layer 140 may be 5 nm or less. However, this is an example, and the disclosure is not limited thereto. For example, the thickness of the conversion layer 140 may be about 10 nm to about 30 nm.

A bilayer structure including the OHC material layer 130 and the conversion layer 140 may be referred to as a spin orbital torque layer in that the bilayer structure can apply spin orbital torque to the magnetization switching layer 150.

The magnetization switching layer 150 may include magnetic material. The magnetization switching layer 150 may include a free layer 151, a pinned layer 155, and a tunnel barrier layer 153 arranged therebetween, both the free layer 151 and the pinned layer 155 including a magnetic material. The pinned layer 155 is a layer in which the direction of magnetic moment is fixed, and the free layer 151 is a layer in which the direction of magnetic moment is switchable.

The free layer 151 and the pinned layer 155 may each include a ferromagnetic metal material. For example, the free layer 151 and the pinned layer 155 may each include at least one ferromagnetic material selected from the group consisting of iron (Fe), cobalt (Co), nickel (Ni), manganese (Mn), a Fe-containing alloy, a Co-containing alloy, a Ni-containing alloy, a Mn-containing alloy, a CoPt alloy, and a Heusler alloy. Furthermore, the free layer 151 and the pinned layer 155 may each be configured to have high perpendicular magnetic anisotropy (PMA). In other words, the perpendicular magnetic anisotropic energy of each of the free layer 151 and the pinned layer 155 may exceed out-of-plane demagnetization energy. In this case, the magnetic moment of the free layer 151 and the pinned layer 155 may be stabilized a direction perpendicular to a plane (e.g., a plane parallel to an X-Y plane), that is, in a thickness direction (Z direction). The free layer 151 and the pinned layer 155 may each include the same material or a different material. For example, to facilitate a change of the magnetization direction of the free layer 151 even with a low current, the free layer 151 may be doped with at least one non-magnetic metal selected from the group consisting of Mg, Ru, Ir, Ti, Zn, Ga, Ta, Al, Mo, Zr, Sn, W, Sb, V, Nb, Cr, Ge, Si, Hf, Tb, Sc, Y, Rh, in, Ca, Sr, Ba, Be, V, Li, Cd, Pb, Ga, and Mo.

The tunnel barrier layer 153 may function as a tunnel barrier for magnetic tunneling junction. The tunnel barrier layer 153 may include an oxide. The tunnel barrier layer 153 may include a Mg oxide of a crystalline substance of the tunnel barrier layer 153. For example, the tunnel barrier layer 153 may include MgO, MgAl₂O₄, or MgTiOₓ. However, the disclosure is not limited thereto, and for example, the tunnel barrier layer 153 may include a boron nitride (BN).

The pinned layer 155 may have a fixed magnetization direction. Although FIGS. 2A and 2B illustrate that, for example, the pinned layer 155 is magnetized in a +Z direction, the disclosure is not limited thereto, and the pinned layer 155 may be magnetized in a-Z direction. The magnetization direction of the pinned layer 155, once set, may not be changed. In contrast, the free layer 151 may have a changeable magnetization direction. The magnetization direction of the free layer 151 may be changed according to the current applied to the OHC material layer 130. For example, the free layer 151 may be magnetized in the +Z direction or −Z direction according to the direction of the current applied to the OHC material layer 130.

The magnetization switching layer 150 has such a magnetic tunnel junction structure, and may be referred to as a tunneling magnetic resistance layer by exhibiting different electrical resistance when the magnetic moment directions of the free layer 151 and the pinned layer 155 are parallel or anti-parallel to each other.

The opposite ends of the OHC material layer 130 may be electrically connected to a first node N1 and a second node N2. The non-heavy metal material included in the OHC material layer 130 exhibits high conductivity, and thus, as illustrated in the drawings, a separate electrode for connecting the first node N1 and the second node N2 may not be provided. An upper electrode 160 electrically connected to a third node N3 may be disposed on the pinned layer 155.

A write current may be applied between the first node N1 and the second node N2. A read current may be applied between any one of the first node N1 and the second node N2, and the third node N3.

Referring to FIG. 2A, when a write current IW greater than or equal to a threshold current or more is applied to the OHC material layer 130 in a direction from the first node N1 to the second node N2, that is, a +X direction, the magnetization direction of the free layer 151 may be switched in the +Z direction. Furthermore, referring to FIG. 2B, when the write current IW greater than or equal to the threshold current is applied to the OHC material layer 130 in a direction from the second node N2 to the first node N1, that is, a −X direction, the magnetization direction of the free layer 151 may be switched in the −Z direction. In FIGS. 2A and 2B, the magnetization directions of the free layer 151 and the pinned layer 155 and the current application direction are examples for convenience of explanation, but the disclosure is not limited thereto. The magnetization directions of the free layer 151 and the pinned layer 155 and the current application direction may be different from those illustrated in FIGS. 2A and 2B.

The magnetic memory device 100 according to an embodiment, in which the OHC material layer 130 and the conversion layer 140 are used as a spin orbital torque layer, is proposed to reduce an operating current and increase an operating speed.

For general spin-orbit torque (SOT)-MRAM which uses Pt that is a heavy metal material in the spin orbital torque layer, it has been known that an operating current density of tens to 100 MA/cm² is needed to obtain an operating speed of 1 nano sec. In order to reduce such an operating current density, the amount of spin current generated in the spin orbital torque layer is increased. A material having high spin Hall conductance (SHC) has been sought to reduce the operating current, and Pt is known as a material that shows the maximum SHC due to the spin Hall effect is Pt. In other words, there is a limitation in employing a material to increase the SHC in place of Pt.

The magnetic memory device 100 according to an embodiment employs the OHC material layer 130 having higher Orbital Hall Conductance than the SHC represented by Pt. The OHC represented by the non-heavy metal material included in the OHC material layer 130 may be greater than the SHC of Pt by several times or more. Furthermore, the magnetic memory device 100 according to an embodiment may employ, with the OHC material layer 130, the conversion layer 140 that can change the orbital current generated by the OHC material layer 130 to a spin current.

Such a bilayer structure may be effective in reducing the operating current compared with a case of utilizing the existing spin Hall effect by a heavy metal material such as Pt and the like.

A process in which a spin current is generated by the OHC material layer 130 may be described as follows.

When a current is applied to the OHC material layer 130, an orbital current is generated, and the generated orbital current flows along a path through the conversion layer 140 contacting the OHC material layer 130 and the free layer 151 contacting the conversion layer 140. In this state, an oxide included in the conversion layer 140, for example, Ni included in NiO may function to change the orbital current to the spin current. Furthermore, in the state in which the conversion layer 140 is in contact with the free layer 151, for example, the free layer 151 includes CoPt, electrons of Ni included in the conversion layer 140 may easily move to Co atoms included in the free layer 151. The Co of the free layer 151 and the Ni of the conversion layer 140 have a similar electron configuration, and in this case, electron conversion efficiency may be further increased.

As such, the magnetic memory device 100, in which the OHC material layer 130 and the conversion layer 140 are used as a spin orbital torque layer, compared with an existing case in which only Pt is employed as a spin orbital torque layer, a relatively large spin current may be generated, and magnetization switching may be available with a low current density.

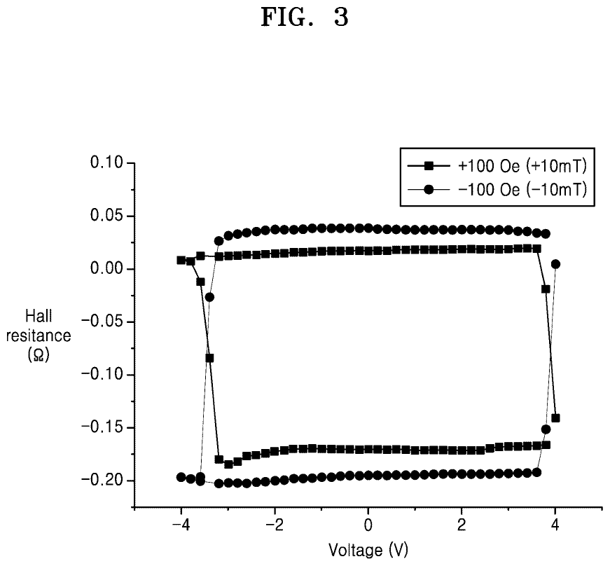

FIG. 3 is a graph experimentally showing a magnetization switching operation of a magnetic memory device according to an embodiment.

In an experiment, Ru of a 2 nm thickness was employed in the OHC material layer 130, NiO of a 1 nm thickness was employed in the conversion layer 140, and CoPt alloy was employed in the free layer 151.

Referring to the graph of FIG. 3, in both cases in which an external magnetic field is 100 Oe and −100 Oe, it is confirmed that Hall resistance sharply changes at an application voltage of a certain value or more, that is, SOT switching is available.

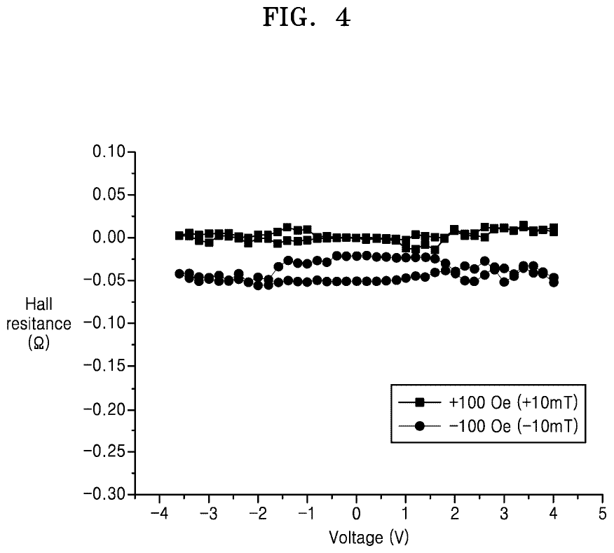

FIG. 4 is a computer-simulated graph of a magnetization switching operation of a magnetic memory device according to a comparative example.

The comparative example differs from the case of FIG. 3 in that the structure does not include the conversion layer.

Referring to the graph of FIG. 4, SOT switching does not occur in the structure of the comparative example in which the conversion layer is not employed.

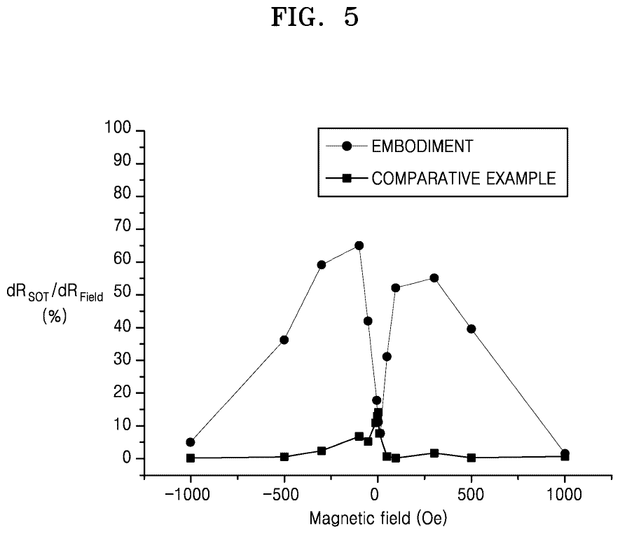

FIG. 5 is a graph showing a comparison of a magnetization switching effect between a magnetic memory device according to an embodiment and a magnetic memory device according to a comparative example.

The vertical axis in the graph of FIG. 5 shows a current induced magnetic reversal effect, and a comparative example and an embodiment have the same structure as those described in FIGS. 3 and 4, respectively.

The embodiment shows a high magnetization switching effect, compared with the comparative example, and for example, under an external magnetic field condition of −300 Oe, the magnetization switching effect of the embodiment amounts to about 30 times of the comparative example.

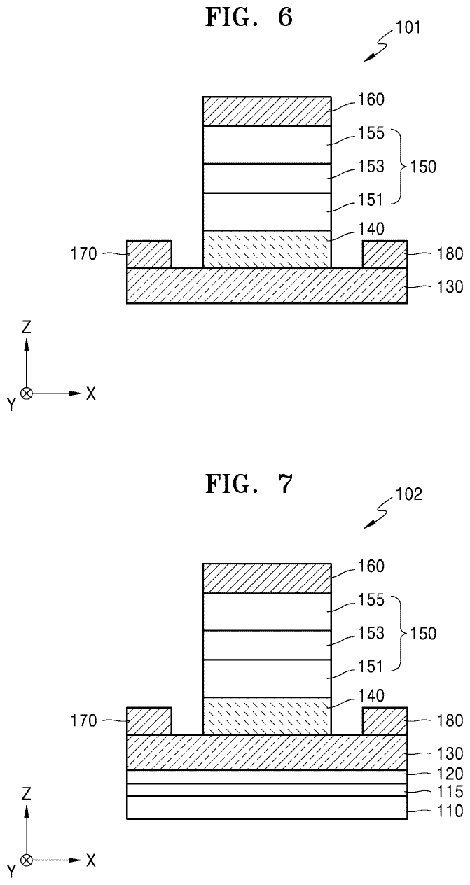

FIG. 6 is a cross-sectional view schematically showing a structure of a magnetic memory device 101 according to another embodiment.

The magnetic memory device 101 differs from the magnetic memory device 100 of FIG. 1 in that the magnetic memory device 101 further includes a first electrode 170 and a second electrode 180 respectively contacting the opposite sides of the OHC material layer 130.

The first electrode 170 and the second electrode 180 may each include a conductive material that is the same as or similar to that of the upper electrode 160. The first electrode 170 and the second electrode 180 may each include the same material as that of the OHC material layer 130.

FIG. 7 is a cross-sectional view schematically showing a structure of a magnetic memory device 102 according to another embodiment.

The magnetic memory device 102 may further include a seed layer 120 disposed adjacent to the OHC material layer 130. The seed layer 120 is a layer used for manufacturing the OHC material layer 130 and may include a material to facilitate the formation of a material included in the OHC material layer 130.

An insulating layer 115 and a substrate 110 may be provided below the seed layer 120. The insulating layer 115 may include, for example, silicon oxide or nitride.

The magnetic memory device 102 may be manufactured by forming the OHC material layer 130 on a lower structure. The lower structure may include the seed layer 120, insulating layer 115, and substrate 110 sequentially stacked. After the OHC material layer 130 is formed on the lower structure, the conversion layer 140 may be formed on top of OHC material layer 130 and the magnetization switching layer 150 may be formed on the conversion layer 150. The first electrode 170 and second electrode 180 may be formed spaced apart from each other on the OHC material layer 130 and spaced apart from the conversion layer 140. The upper electrode 160 may be formed on top of the pinned layer 155 of the magnetization switching layer 150.

The substrate 110 and the insulating layer 115, with the seed layer 120, are layers accompanied in a process of manufacturing the OHC material layer 130, and may be omitted. For example, the magnetic memory device 101 in FIG. 6 may be provided by omitting or removing the substrate 110, insulating layer 115, and seed layer 120.

FIG. 8 is a cross-sectional view schematically showing a structure of a magnetic memory device 103 according to another embodiment.

The magnetic memory device 103 may further include magnetic layers 191 and 192 that are arranged adjacent to the OHC material layer 130.

The magnetic layer 191 may be disposed between the OHC material layer 130 and the first electrode 170, and the magnetic layer 192 may be disposed between the OHC material layer 130 and the second electrode 180.

The magnetic layers 191 and 192 may be provided to replace an external magnetic field needed for the operation of the magnetic memory device 103.

The magnetic layers 191 and 192 may be magnets that provide, for example, a stray magnetic field. The magnetic layers 191 and 192 may each include Co, Fe, Ni, CoFe, CoNi, FeNi, FeB, CoFeB, or CoB. Although the magnetic layers 191 and 192 are each illustrated as a single layer, the disclosure is not limited thereto, and the magnetic layers 191 and 192 may each be provided as a multilayer.

The magnetic memory device 103 according to an embodiment may not need application of an external magnetic field in a horizontal direction when switching the magnetization of the free layer 151.

Although FIG. 8 illustrates that two magnetic layers 191 and 192 are provided, only one thereof may be provided.

The magnetic memory device 102 may be manufactured by forming the OHC material layer 130 on a lower structure. The lower structure may include the first electrode 170 and the second electrode 180 spaced apart from each other on a substrate (not shown) and the magnetic layers 191 and 192 on the first electrode 170 and the second electrode 180. After the OHC material layer 130 is formed on the lower structure, the conversion layer 140 may be formed on top of OHC material layer 130 and the magnetization switching layer 150 may be formed on the conversion layer 150. The upper electrode 160 may be formed on top of the pinned layer 155 of the magnetization switching layer 150.

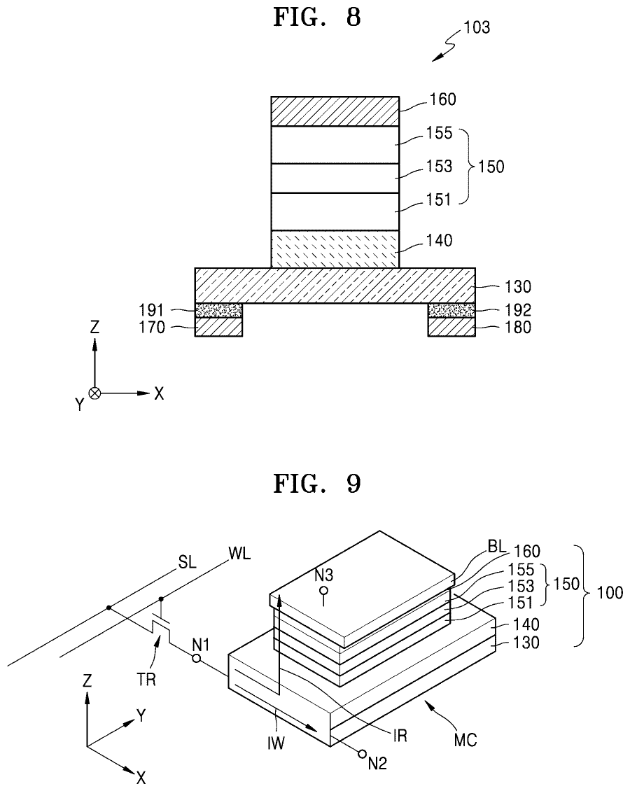

FIG. 9 schematically illustrates one memory cell MC including the magnetic memory device 100 according to an embodiment.

Referring to FIG. 9, the memory cell MC may include the magnetic memory device 100 and a switching device TR connected thereto. The switching device TR may be a thin film transistor. The memory cell MC may be connected between a bit line BL and a word line WL. The bit line BL and the word line WL may be arranged to intersect with each other, and the memory cell MC may be located at an intersection therebetween. The bit line BL may be electrically connected to the upper electrode 160 of the magnetic memory device 100. When the upper electrode 160 is omitted, the bit line BL may be electrically connected to the pinned layer 155. The word line WL may be connected to a gate of the switching device TR. Furthermore, a first source/drain electrode of the switching device TR may be electrically connected to the OHC material layer 130 of the magnetic memory device 100, and a second source/drain electrode thereof may be electrically connected to a source line SL.

Although FIG. 9 illustrates that the memory cell MC includes the magnetic memory device 100 of FIG. 1, the memory cell MC according to some embodiments may have a structure of any one of the magnetic memory devices 101, 102, and 103 of FIGS. 6 to 8, or a structure modified therefrom.

In such a structure, the write current IW and a read current IR may be applied to the memory cell MC through the word line WL and the bit line BL. For example, the write current IW of a threshold current or more may flow in a path between the first node N1 and the second node N2 at the opposite sides of the OHC material layer 130. To this end, the first source/drain electrode of the switching device TR may be connected to the first node N1 of the OHC material layer 130. Although it is not illustrated, a ground electrode may be connected to the second node N2 of the OHC material layer 130. Then, the magnetization direction of the free layer 151 may be changed to the +Z direction or −Z direction according to the direction of the current applied to the OHC material layer 130. Furthermore, the read current IR may flow in a path between the first node N1 of the OHC material layer 130 and the third node N3 above the bit line BL. For example, a resistance value of the magnetic memory device 100 may be read by applying a current lower than the threshold current to the first node N1 and measuring a current flowing between the OHC material layer 130 and the bit line BL.

Although FIG. 9 illustrates the write current IW flowing in a direction from the first node N1 to the second node N2, the write current IW alternatively may be applied to the OHC material layer 130 so the write current IW flows from the second node N2 to the first node N1 like as described in FIG. 2B.

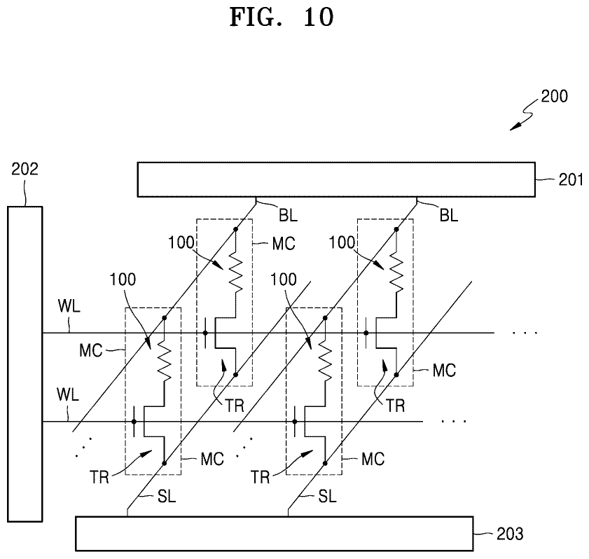

FIG. 10 is a circuit diagram schematically showing a configuration of a memory device 200 including a plurality of memory cells MCs illustrated in FIG. 9. Referring to FIG. 10, the memory device 200 may include a plurality of bit lines BL, a plurality of word lines WL, a plurality of source lines SL, a plurality of memory cells MC each located at an intersection where the bit lines BL and the word lines WL meet each other, a bit line driver 201 that applies a current to the bit lines BL, a word line driver 202 that applies a current to the word lines WL, and a source line driver 203 that applies a current to the source lines SL. Each memory cell MC may have the configuration illustrated in FIG. 10. The memory device 200 illustrated in FIG. 10 may be, for example, magnetic random-access memory (MRAM), and may be used in electronic devices using a non-volatile memory. The memory device 200 may be SOT-MRAM.

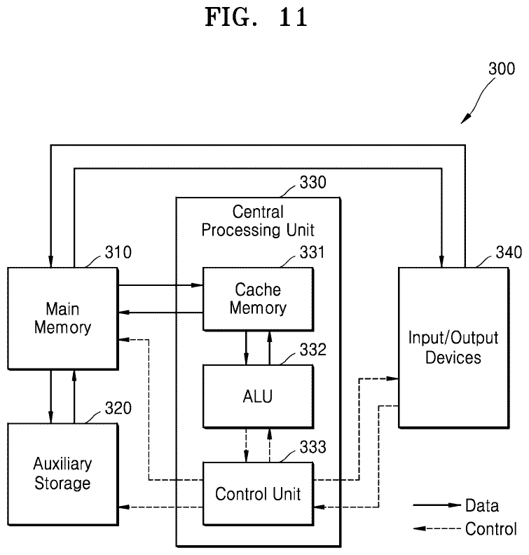

The memory device 200 described above may be used to store data in various electronic devices. FIG. 11 is a conceptual view schematically showing a device architecture to be applied to an electronic device 300 according to some embodiments. Referring to FIG. 11, the electronic device 300 may include a main memory 310, an auxiliary storage 320, a central processing unit (CPU) 330, and an input/output device 340 (e.g., keyboard, display, mouse). The CPU 330 may include a cache memory 331, an arithmetic logic unit (ALU) 332, and a control unit 333. The cache memory 331 may include static random-access memory (SRAM). The main memory 310 may include a DRAM device, and the auxiliary storage 320 may include the memory device 200 according to an embodiment. Alternatively, the cache memory 331, the main memory 310, and the auxiliary storage 320 may all include the memory device 200 according to an embodiment. In some cases, the electronic device 300 may be implemented in the form in which computing unit devices and memory unit devices are adjacent to each other in one chip).

The magnetic memory device described above has a simplified structure and is capable of magnetization switching with a low operating current.

The magnetic memory device described above may exhibit high-speed switching characteristics and high durability.

It should be understood that described above magnetic memory device and electronic device including the same described herein should be considered in a descriptive sense only and not for purposes of limitation. Descriptions of features or aspects within each embodiment should typically be considered as available for other similar features or aspects in other embodiments.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While one or more embodiments have been described with reference to the figures, it will be understood by those of ordinary skill in the art that various changes in form and details may be made therein without departing from the spirit and scope of inventive concepts as defined by the following claims.

What is claimed is:

1. A magnetic memory device comprising:
an orbital Hall conductance (OHC) material layer including a non-heavy metal material and configured to generate an orbital Hall current;
a conversion layer on the OHC material layer, the conversion layer being configured to convert an orbital Hall current generated by the OHC material layer into a spin Hall current, and the conversion layer including an oxide; and
a magnetization switching layer on the conversion layer and including a magnetic material.

2. The magnetic memory device of claim 1, wherein the conversion layer includes an oxide containing Ni.

3. The magnetic memory device of claim 1, wherein the conversion layer includes a Ni oxide of a non-stoichiometric composition.

4. The magnetic memory device of claim 1, wherein the conversion layer includes an oxide of a ferromagnetic material.

5. The magnetic memory device of claim 1, wherein the conversion layer includes an Al oxide, a Tb oxide, a Mg oxide, a Si oxide, a Ti oxide, a V oxide, a Cr oxide, a Fe oxide, a Co oxide, a Zr oxide, a Y oxide, a Nb oxide, a Ru oxide, a Hf oxide, a W oxide, a rare-earth element, or a transition metal oxide.

6. The magnetic memory device of claim 1, wherein the OHC material layer includes Ca, Sc, Ti, V, Cr, Mn, Fe, Co, Ni, Y, Zr, Nb, Mo, or Ru.

7. The magnetic memory device of claim 1, wherein the OHC material layer includes a 3d transition metal or a 4d transition metal.

8. The magnetic memory device of claim 1, wherein the OHC material layer does not include Pt, Ta, or beta-W.

9. The magnetic memory device of claim 1, wherein
the magnetization switching layer includes a free layer, a tunnel barrier layer, and a pinned layer, which are sequentially arranged on the conversion layer.

10. The magnetic memory device of claim 1, further comprising:
a first electrode and a second electrode electrically connected to opposite sides of the OHC material layer, respectively; and
a third electrode electrically connected to the pinned layer.

11. The magnetic memory device of claim 10, wherein
the first electrode and second electrode each include a same material as the OHC material.

12. The magnetic memory device of claim 10, further comprising:
a magnetic layer, wherein
the magnetic layer is between the first electrode and the OHC material layer or the magnetic layer is between the second electrode and the OHC material layer.

13. The magnetic memory device of claim 1, further comprising:
a seed layer; and
an insulating layer, wherein
the seed layer is between the insulating layer and the OHC material layer.

14. The magnetic memory device of claim 1, wherein a thickness of the OHC material layer is 0.5 nm or more.

15. The magnetic memory device of claim 1, wherein
a thickness of the conversion layer is 0.5 nm to 5 nm.

16. A memory device comprising:
a plurality of memory cells, wherein
each of the plurality of memory cells include a magnetic memory device and a switching device connected to the magnetic memory device,
the magnetic memory device includes an orbital Hall conductance (OHC) material layer, a conversion layer on the OHC material layer, and a magnetization switching layer on the conversion layer,
the OHC material layer includes a non-heavy metal material and is configured to generate an orbital Hall current,
the conversion layer is configured to convert an orbital Hall current generated by the OHC material layer into a spin Hall current,
the conversion layer includes an oxide; and
the magnetization switching layer includes a magnetic material.

17. The memory device of claim 16, wherein the conversion layer includes an oxide containing Ni.

18. The memory device of claim 16, wherein the conversion layer includes a Ni oxide of a non-stoichiometric composition.

19. The memory device of claim 16, wherein the conversion layer includes an Al oxide, a Tb oxide, a Mg oxide, a Si oxide, a Ti oxide, a V oxide, a Cr oxide, a Fe oxide, a Co oxide, a Zr oxide, a Y oxide, a Nb oxide, a Ru oxide, a Hf oxide, a W oxide, a rare-earth element, or a transition metal oxide.

20. The memory device of claim 16, wherein the OHC material layer includes Ca, Sc, Ti, V, Cr, Mn, Fe, Co, Ni, Y, Zr, Nb, Mo, or Ru.
